(19) United States
(12) Patent Application Publication
(10) Pub. No.: US 2025/0279727 A1
(43) Pub. Date: Sep. 4, 2025

(54) ENCLOSURE FOR ISOLATED CONVERTER AND ISOLATED CONVERTER USING SAME

(71) Applicant: LS ELECTRIC CO., LTD., Anyang-si, Gyeonggi-do (KR)

(72) Inventor: Jeong Woo LIM, Anyang-si, Gyeonggi-do (KR)

(21) Appl. No.: 18/282,965

(22) PCT Filed: Feb. 14, 2022
(86) PCT No.: PCT/KR2022/002154

§ 371 Date: Mar. 13, 2024

(30) Foreign Application Priority Data
Mar. 25, 2021 (KR) 10-2021-0038987

(51) Int. Cl. H02M 7/00; H05K 7/14

(52) U.S. Cl. CPC H02M 7/003; H05K 7/1427

(57) ABSTRACT

An enclosure for an isolated converter and an isolated converter using the same are provided. The enclosure for an isolated converter, according to an embodiment of the present invention, may include a main body having a primary-side space and a secondary-side space. The main body may include a partition wall provided to vertically separate the primary-side space and the secondary-side space from each other, and an upper wall and a lower wall provided above and below the partition wall, respectively.

### CROSS-REFERENCE TO RELATED APPLICATION

This application is a National Stage of International Application No. PCT/KR2022/002154, filed on Feb. 14, 2022, which claims priority to and the benefit of Korean Patent Application No. 10-2021-0038987, filed on Mar. 25, 2021, the disclosure of which is incorporated herein by reference in its entirety.

### FIELD

The present disclosure relates to an enclosure for an isolated converter and an isolated converter using the same.

### BACKGROUND

In general, a DC-DC converter or an AC-DC converter is provided in a switching mode power supply (SMPS) to stably supply control power in a high voltage environment. A converter (DC-DC or AC-DC converter) is a device that arbitrarily varies the output voltage with respect to the input power. Here, the converter has a primary-side input and a secondary-side output.

In addition, the converter can be divided into an isolated type that provides an isolation function between input/output voltages and a non-isolated type that does not provide this. Here, the isolation performance of the isolated converter is determined according to the structure of the enclosure.

In an isolated SMPS or an isolated converter, ‘isolated’ means to include a transformer structure consisting of primary and secondary coils that are magnetically connected but electrically separated/isolated. Therefore, it is important to maintain electrical isolation between the primary coil and the secondary coil at the time of high voltage input.

Meanwhile, the isolated converter is required to reduce manufacturing costs and miniaturize for installation and operation. However, the conventional isolated converter has a problem in that it cannot simultaneously satisfy both isolation performance and minimization of the overall size due to the structure of the enclosure.

### SUMMARY

The present disclosure is directed to providing an enclosure for an isolated converter and an isolated converter using the same, minimizing the overall size while maintaining isolation performance.

In order to solve the above technical problems, the enclosure for an isolated converter according to an embodiment of the present disclosure may include a main body having a primary-side space and a secondary-side space. Here, the main body may include a partition wall provided to vertically separate the primary-side space and the secondary-side space from each other; and an upper wall and a lower wall provided above and below the partition wall, respectively.

In an embodiment of the present disclosure, the partition wall may be provided in the center of the main body.

The enclosure for an isolated converter according to an embodiment of the present disclosure may further include side plates provided on both sides of the main body.

The enclosure for an isolated converter according to an embodiment of the present disclosure may further include input/output terminals provided on the outside of the side plates.

In an embodiment of the present disclosure, the primary-side space and the secondary-side space may be defined by the upper wall, the lower wall and the partition wall.

The enclosure for an isolated converter according to an embodiment of the present disclosure may further include a first stepped portion provided from the partition wall to form a step difference with the upper wall and the lower wall, in each of the primary-side space and the secondary-side space.

The enclosure for an isolated converter according to an embodiment of the present disclosure may further include a second stepped portion provided from the first stepped portion to the opposite side of the partition wall and having a groove portion in the center, in each of the primary-side space and the secondary-side space.

The main body of the enclosure for an isolated converter according to an embodiment of the present disclosure may have a length in the vertical direction longer than a length in the horizontal direction so that an area of a bottom surface facing an installation surface is minimized.

In addition, in order to solve the above technical problems, the isolated converter according to an embodiment of the present disclosure may include an enclosure as described above; a primary-side core and a primary-side PCB disposed in the primary-side space; and a secondary-side core and a secondary-side PCB disposed in the secondary-side space.

In an embodiment of the present disclosure, the primary-side core and the secondary-side core may be disposed on the partition wall side.

In an embodiment of the present disclosure, the primary-side PCB and the secondary-side PCB may be disposed on opposite sides of the primary-side core and the secondary-side core, respectively.

In an embodiment of the present disclosure, an elastic pressing part maintaining a distance between the primary-side core and the secondary-side core may be further included.

The above disclosure provides a partition wall that divides a primary-side space and a secondary-side space, and an upper wall and a lower wall above and below the partition wall, and thus, can maximize the creepage distance compared to an enclosure of the same standard, thereby minimizing the overall size while maintaining the isolation performance.

In addition, by providing an enclosure to maximize the creepage distance compared to an enclosure of the same standard, the present disclosure can reduce the manufacturing cost because the enclosure and the isolated converter using the enclosure can be miniaturized.

### BRIEF DESCRIPTION OF THE DRAWINGS

FIG. 1 is a perspective view of an isolated converter according to an exemplary embodiment of the present disclosure.

FIG. 2 is a cross-sectional view of an isolated converter according to an exemplary embodiment of the present disclosure.

FIG. 3 is a cross-sectional perspective view of an enclosure for an isolated converter according to an exemplary embodiment of the present disclosure.

FIG. 4 is a perspective view of an enclosure for an isolated converter according to an exemplary embodiment of the present disclosure.

FIG. 5 is an exemplary view for explaining the creepage distance of an enclosure for an isolated converter according to an exemplary embodiment of the present disclosure.

### DESCRIPTION OF SYMBOLS

10: isolated converter 11: first converter
12: second converter 100: enclosure for an isolated converter
110: main body 111: primary-side space
112: partition wall 113: secondary-side space
114: upper wall 114a, 116a: first stepped portion
114b, 116b: second stepped portion 114c, 116c: groove portion
115a, 117a: first fastening groove 115b, 117b: second fastening groove
115c, 117c: third fastening groove 116: lower wall
120: side plate 130: input/output terminal

### DETAILED DESCRIPTION

Hereinafter, in order to fully understand the configuration and effects of the present disclosure, preferred embodiments of the present disclosure will be described with reference to the accompanying drawings. However, the present disclosure is not limited to the embodiments disclosed below, and may be embodied in various forms and various modifications may be made. Rather, the description of the present disclosure is provided so that the present disclosure will be thorough and complete and will fully convey the scope of the disclosure to those of ordinary skill in the art. In the accompanying drawings, the size of the elements is enlarged compared to actual ones for the convenience of description, and the ratio of each element may be exaggerated or reduced.

Terms such as ‘first’ and ‘second’ may be used to describe various elements, but, the above elements should not be limited by the terms above. The above terms may be used only for the purpose of distinguishing one element from another. For example, without departing from the scope of the present disclosure, a ‘first element’ may be named a ‘second element’ and similarly, a ‘second element’ may also be named a ‘first element.’ In addition, expressions in the singular include plural expressions unless explicitly expressed otherwise in the context. Unless otherwise defined, terms used in the embodiments of the present disclosure may be interpreted as meanings commonly known to those of ordinary skill in the art.

Hereinafter, an isolated converter and an enclosure for an isolated converter of an embodiment of the present disclosure will be described with reference to the drawings.

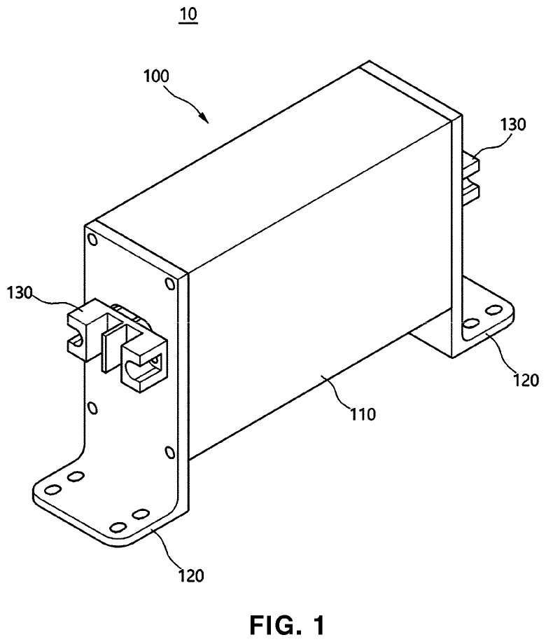

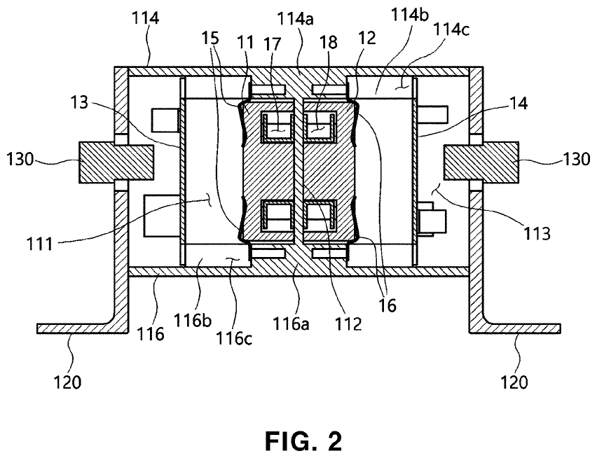

FIG. 1 is a perspective view of an isolated converter according to an exemplary embodiment of the present disclosure, and FIG. 2 is a cross-sectional view according to an exemplary embodiment of the present disclosure.

As shown in FIGS. 1 and 2, the isolated converter 10 according to an embodiment of the present disclosure may include an enclosure 100 for an isolated converter, a primary-side core 11, a secondary-side core 12, a primary-side PCB 13 and a secondary-side PCB 14.

In particular, the main body 110 of the enclosure 100 for an isolated converter has a rectangular parallelepiped shape in which the vertical length is longer than the horizontal length. This shape of the main body 110 is more advantageous for isolation.

If the horizontal length is longer than the vertical length, the area where the lower surface of the SMPS faces the fixed bottom surface is relatively widened, and the support inevitably becomes larger, which is more disadvantageous to isolation.

The enclosure 100 for an isolated converter may include a main body 110, a side plate 120, and an input/output terminals 130, for accommodating the primary-side core 11, the secondary-side core 12, the primary-side PCB 13 and the secondary-side PCB 14, which are the main components of the isolated converter 10. Here, the enclosure 100 for an isolated converter is not limited to the isolated converter and may be applied to a power semiconductor transformer.

In addition, elastic pressing parts 15 and 16 for fixing the primary-side core 11 and the secondary-side core 12 to maintain magnetic force may be included.

The main body 110 may be formed in a shape divided into two parts. For example, the main body 110 may be formed in a quadrangular shape.

The main body 110 may include a primary-side space 111 for accommodating the primary-side core 11 and the primary-side PCB 13 and a secondary-side space 113 for accommodating the secondary-side core 12 and the secondary-side PCB 14. In the drawing, a space on the left side of a partition wall 112 may be the primary-side space 111 and a space on the right side of the partition wall 112 may be the secondary-side space 113.

As shown in FIG. 2, a partition wall 112 may be provided inside the main body 110 to vertically separate the primary-side space 111 and the secondary-side space 113. That is, the primary-side space 111 and the secondary-side space 113 may be divided by the partition wall 112 provided inside the main body 110.

In addition, the main body 110 may include an upper wall 114 provided on the upper side of the partition wall 112 and a lower wall 116 provided on the lower side of the partition wall 112.

The side plate 120 may be provided on both sides of the main body 110. The side plate 120 may be provided to seal the primary-side space 111 and the secondary-side space 113 separated from the main body 110 by the partition wall 112.

The input/output terminals 130 may be provided on the outside of the side plate 120. For example, in the drawing, the left side of the main body 110 may be an input terminal, and the right side of the main body 110 may be an output terminal. That is, the input terminal may be provided on the primary side of the isolated converter 10, and the output terminal may be provided on the secondary side of the isolated converter 10.

The primary-side core 11 may be disposed in the primary-side space 111 of the enclosure 100 for an isolated converter. Here, the primary-side core 11 may be disposed on the partition wall 112 side within the primary-side space 111.

The secondary-side core 12 may be disposed in the secondary-side space 113 of the enclosure 100 for an isolated converter. Here, the secondary-side core 12 may be disposed on the partition wall 112 side within the secondary-side space 113.

As shown in FIG. 2, the primary-side core 11 and the secondary-side core 12 may be provided to face each other with the partition wall 112 interposed therebetween.

A primary-side coil 17 and a secondary-side coil 18 are wound around the primary-side core 11 and the secondary-side core 12, respectively, and the primary-side core 11 and the secondary-side core 12 are spaced apart for electrical isolation. The separation distance at this time is the maximum distance that can maintain a certain level of magnetic connection strength.

In this state, if the gap between the primary-side core 11 and the secondary-side core 12 is slightly widened due to impact or assembly play, the magnetic connection strength is weakened, so it is necessary to maintain the correct position.

To this end, in the present disclosure, the primary-side core 11 and the secondary-side core 12 are fixed by elastic pressing parts 15 and 16, respectively, to fix their positions. The primary-side elastic pressing part 15 presses the primary-side core 11 in the direction of the secondary-side core 12 to prevent an increase in the distance between the primary-side core 11 and the secondary-side core 12 in advance. The same applies to the secondary-side elastic pressing part 16. Therefore, it is possible to prevent the magnetic connection from being weakened due to external impact or assembly play. In addition, when only the elastic pressing parts 15 and 16 are removed, the primary-side core 11 and the secondary-side core 12 can be separated, which is advantageous for maintenance in the future.

The primary-side PCB 13 may be disposed in the primary-side space 111 of the enclosure 100 for an isolated converter. Here, the primary-side PCB 13 may be disposed on the opposite side of the primary-side core 11 within the primary-side space 111. That is, the primary-side PCB 13 may be disposed on the input/output terminals 130 side. In addition, passive elements and switching elements constituting the converter circuit may be mounted to the primary-side PCB 13.

The secondary-side PCB 14 may be disposed in the secondary-side space 113 of the enclosure 100 for an isolated converter. Here, the secondary-side PCB 14 may be disposed on the opposite side of the secondary-side core 12 within the secondary-side space 113. That is, the secondary-side PCB 14 may be disposed on the input/output terminals 130 side. In addition, passive elements and switching elements constituting the converter circuit may be mounted to the secondary-side PCB 14.

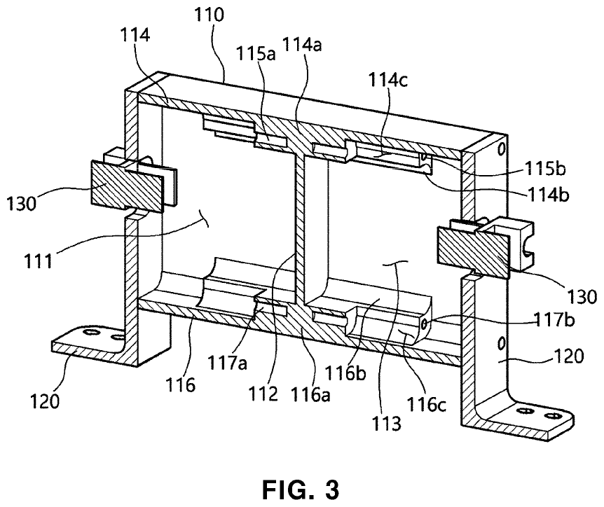

Hereinafter, the enclosure 100 for an isolated converter according to an embodiment of the present disclosure will be described in more detail with reference to FIGS. 3 to 5.

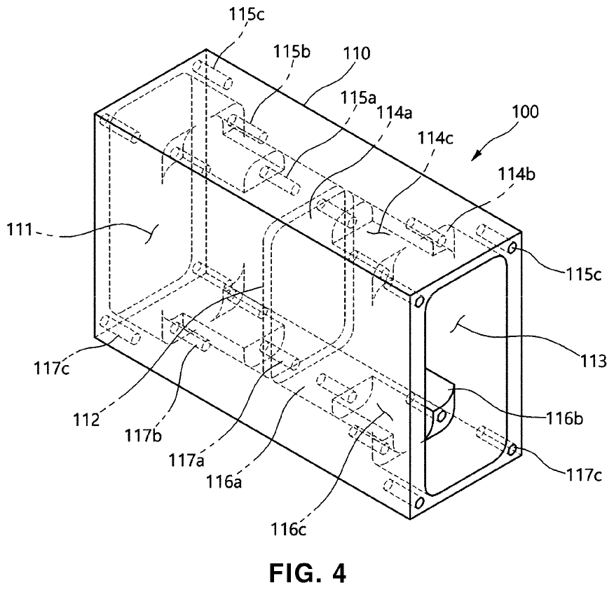

FIG. 3 is a cross-sectional perspective view of an enclosure for an isolated converter according to an exemplary embodiment of the present disclosure, and FIG. 4 is a perspective view of an enclosure for an isolated converter according to an exemplary embodiment of the present disclosure.

As shown in the drawings, the partition wall 112 dividing the primary-side space 111 and the secondary-side space 113 may be provided at the center of the main body 110. That is, the main body 110 may have a bilaterally symmetrical structure around the partition wall 112.

In the drawings and the description below, it should be understood that the description of the primary-side space 111 can be equally applied to the secondary-side space 113.

As shown in FIG. 3, the primary-side space 111 and the secondary-side space 113 may be defined by an upper wall 114, a partition wall 112, and a lower wall 116. That is, as shown in FIG. 4, the enclosure 100 for an isolated converter may have a structure in which both sides are open, and may include a primary-side space 111 and a secondary-side space 113 on both sides around the partition wall 112.

In each of the primary-side space 111 and the secondary-side space 113, a first stepped portion 114a forming a step difference with the upper wall 114 may be provided. Here, the first stepped portion 114a may be provided with a step inward from the upper wall 114. That is, the first stepped portion 114a may have a greater thickness than the upper wall 114.

Similarly, in each of the primary-side space 111 and the secondary-side space 113, a first stepped portion 116a forming a step difference with the lower wall 116 may be provided. Here, the first stepped portion 116a may be provided with a step inward from the lower wall 116. That is, the first stepped portion 116a may have a greater thickness than the lower wall

As shown in FIG. 2, in the primary-side space 111, a primary-side core 11 may be disposed between the first stepped portion 114a of the upper wall 114 and the first stepped portion 116a of the lower wall 116. Similarly, in the secondary-side space 113, a secondary-side core 12 may be disposed between the first stepped portion 114a of the upper wall 114 and the first stepped portion 116a of the lower wall 116.

Here, a first fastening groove 115a may be provided in the first stepped portion 114a provided on the upper wall 114. The first fastening groove 115a may be provided on the opposite side of the partition wall 112 at the center of the first stepped portion 114a. That is, the first fastening groove 115a may be exposed to the outside from a groove portion 114c.

Similarly, a first fastening groove 117a may be provided in the first stepped portion 116a provided on the lower wall 116. The first fastening groove 117a may be provided on the opposite side of the partition wall 112 at the center of the first stepped portion 116a. That is, the first fastening groove 117a may be exposed to the outside from a groove portion 116c.

As shown in FIG. 2, a fastening screw (not shown) is inserted and coupled into the first fastening grooves 115a and 117a in a state where the primary-side core 11 is disposed between the first stepped portion 114a of the upper wall 114 and the first stepped portion 116a of the lower wall 116 in the primary-side space 111, whereby the primary-side core 11 may be coupled to the partition wall 112 side within the primary-side space 111.

Similarly, a fastening screw (not shown) is inserted and coupled into the first fastening grooves 115a and 117a in a state where the secondary-side core 12 is disposed between the first stepped portion 114a of the upper wall 114 and the first stepped portion 116a of the lower wall 116 in the secondary-side space 113, whereby the secondary-side core 12 may be coupled to the partition wall 112 side within the secondary-side space 113.

In each of the primary-side space 111 and the secondary-side space 113, a second stepped portion 114b provided on the opposite side of the partition wall 112 from the first stepped portion 114a may be provided. Here, the second stepped portion 114b may have the same thickness as the first stepped portion 114a. In addition, the second stepped portion 114b may have a groove portion 114c in the center.

For example, the second stepped portion 114b may be provided so that the distance between the distal end and the partition wall 112 is greater than half of the primary-side space 111 or the secondary-side space 113. That is, the distal end of the second stepped portion 114b may be disposed closer to the side plate 120 than the partition wall 112 in each of the primary-side space 111 and the secondary-side space 113. Here, the distal end means a portion where a step is formed between the second stepped portion 114b and the upper wall 114.

Similarly, in each of the primary-side space 111 and the secondary-side space 113, a second stepped portion 116b provided on the opposite side of the partition wall 112 from the first stepped portion 116a may be provided. Here, the second stepped portion 116b may have the same thickness as the first stepped portion 116a. In addition, the second stepped portion 116b may have a groove portion 116c in the center.

For example, the second stepped portion 116a may be provided so that the distance between the distal end and the partition wall 112 is greater than half of the primary-side space 111 or the secondary-side space 113. That is, the distal end of the second stepped portion 116b may be disposed closer to the side plate 120 than the partition wall 112 in each of the primary-side space 111 and the secondary-side space 113. Here, the distal end means a portion where a step is formed between the second stepped portion 116b and the lower wall 116.

As shown in FIG. 2, in the primary-side space 111, a primary-side PCB 13 may be disposed between the distal end of the second stepped portion 114b of the upper wall 114 and the distal end of the second stepped portion 116b of the lower wall 116. Similarly, in the secondary-side space 113, a secondary-side PCB 14 may be disposed between the distal end of the second stepped portion 114b of the upper wall 114 and the distal end of the second stepped portion 116b of the lower wall 116.

Here, a second fastening groove 115b may be provided in the second stepped portion 114b provided on the upper wall 114. The second fastening groove 115b may be provided on the opposite side of the partition wall 112 from both sides of the second stepped portion 114b. That is, the second fastening groove 115b may be exposed to the outside from a side of the partition wall 112.

Similarly, a second fastening groove 117b may be provided in the second stepped portion 116b provided on the lower wall 116. The second fastening groove 117b may be provided on the opposite side of the partition wall 112 from both sides of the second stepped portion 116b. That is, the second fastening groove 117b may be exposed to the outside from a side of the partition wall 112.

As shown in FIG. 2, a fastening screw (not shown) is inserted and coupled into the second fastening grooves 115b and 117b in a state where the primary-side PCB 13 is disposed between the distal end of the second stepped portion 114b of the upper wall 114 and the distal end of the second stepped portion 116b of the lower wall 116 in the primary-side space 111, whereby the primary-side PCB 13 may be coupled within the primary-side space 111.

Similarly, a fastening screw (not shown) is inserted and coupled into the second fastening grooves 115b and 117b in a state where the secondary-side PCB 14 is disposed between the distal end of the second stepped portion 114b of the upper wall 114 and the distal end of the second stepped portion 116b of the lower wall 116 in the secondary-side space 113, whereby the secondary-side PCB 14 may be coupled within the secondary-side space 113.

In addition, third fastening grooves 115c and 117c may be provided on both sides of the main body 110. The third fastening grooves 115c and 117c may be provided near four corners on both sides of the main body 110.

As shown in FIG. 3, in a state where the side plates 120 are disposed on both sides of the main body 110, fastening screws (not shown) are inserted and coupled into the third fastening grooves 115c and 117c, whereby the side plates 120 may be coupled to both sides of the main body 110.

Meanwhile, the standards related to the isolation performance of the enclosure 100 for an isolated converter stipulate the insulation distance so that it can be applied during product design. Here, insulation distance is divided into clearance distance and creepage distance. The clearance distance means a distance in which the primary-side core 11 and the secondary-side core 12 directly face each other. The creepage distance is a distance between the primary-side core 11 and the secondary-side core 12 and means the shortest distance along the surface of the solid dielectric.

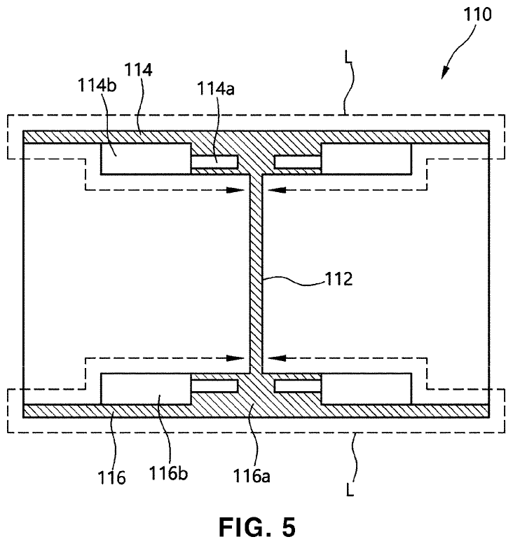

In the enclosure 100 for an isolated converter, since the primary-side core 11 and the secondary-side core 12 are blocked by the partition wall 112 and do not face each other, the clearance distance is not defined. The creepage distance will be described in more detail with reference to FIG. 5.

FIG. 5 is an exemplary view for explaining the creepage distance of an enclosure for an isolated converter according to an exemplary embodiment of the present disclosure.

As shown in FIG. 3, since the primary-side core 11 and the secondary-side core 12 disposed in the enclosure 100 for an isolated converter are disposed to face each other with respect to the partition wall 112, the creepage distance may be defined as a distance from the partition wall 112 on the primary-side space 111 side to the partition wall 112 on the secondary-side space 113 side.

For example, the creepage distance L by the enclosure 100 for an isolated converter is a distance formed by the first stepped portion 114a, the second stepped portion 114b, the upper wall 114, and the top surface of the main body 110 with the partition wall 112 as the center.

Similarly, the creepage distance L by the enclosure 100 for an isolated converter is a distance formed by the first stepped portion 116a, the second stepped portion 116b, the lower wall 116, and the bottom surface of the main body 110 with the partition wall 112 as the center.

Accordingly, according to an embodiment of the present disclosure, by forming the creepage distance on both sides of the enclosure 100 for an isolated converter with the partition wall 112 as the center, it is possible to maximize the creepage distance compared to an enclosure of the same standard, thereby minimizing the overall size while maintaining the isolation performance.

In addition, according to an embodiment of the present disclosure, manufacturing costs can be reduced because the enclosure 100 for an isolated converter and the isolated converter 10 using the enclosure 100 for an isolated converter can be miniaturized.

While the present disclosure has been described in connection with what is presently considered to be practical exemplary embodiments, those skilled in the art may understand that the disclosure is not limited to the disclosed embodiments, but, on the contrary, is intended to cover various modifications and equivalent arrangements included within the spirit and scope of the appended claims. Accordingly, the true technical protection scope of the present disclosure shall be determined according to the attached claims.

The present disclosure is a technology for improving the isolation performance and reducing the size of an isolated converter using the law of nature, and has industrial applicability.

What is claimed is:

1. A enclosure for an isolated converter, comprising:
a main body having a primary-side space and a secondary-side space,
wherein the main body comprises:
a partition wall provided to vertically separate the primary-side space and the secondary- side space from each other; and
an upper wall and a lower wall provided above and below the partition wall, respectively.

2. The enclosure for an isolated converter of claim 1, wherein the partition wall is provided in the center of the main body.

3. The enclosure for an isolated converter of claim 1, further comprising side plates provided on both sides of the main body.

4. The enclosure for an isolated converter of claim 3, further comprising input/output terminals provided on the outside of the side plates.

5. The enclosure for an isolated converter of claim 1, wherein the primary-side space and the secondary-side space are defined by the upper wall, the lower wall and the partition wall.

6. The enclosure for an isolated converter of claim 1, further comprising a first stepped portion provided from the partition wall to form a step difference with the upper wall and the lower wall, in each of the primary-side space and the secondary-side space.

7. The enclosure for an isolated converter of claim 6, further comprising a second stepped portion provided from the first stepped portion to the opposite side of the partition wall and having a groove portion in the center, in each of the primary-side space and the secondary-side space.

8. The enclosure for an isolated converter of claim 1, wherein the main body has a length in the vertical direction longer than a length in the horizontal direction so that an area of a bottom surface facing an installation surface is minimized.

9. An isolated converter, comprising:
an enclosure according to any one of claims 1 to 8;
a primary-side core and a primary-side PCB disposed in the primary-side space; and
a secondary-side core and a secondary-side PCB disposed in the secondary-side space.

10. The isolated converter of claim 9, wherein the primary-side core and the secondary-side core are disposed on the partition wall side.

11. The isolated converter of claim 9, wherein the primary-side PCB and the secondary-side PCB are disposed on opposite sides of the primary-side core and the secondary-side core, respectively.

12. The isolated converter of claim 10, further comprising an elastic pressing part maintaining a distance between the primary-side core and the secondary-side core.
